(19) United States
(12) Patent Application Publication
(10) Pub. No.: US 2008/0150551 A1
(43) Pub. Date: Jun. 26, 2008

(54) Capacitance measurement circuit and capacitance measurement method thereof

(75) Inventor: Han-su Kim, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/002,419

(22) Filed: Dec. 17, 2007

(30) Foreign Application Priority Data
Dec. 21, 2006 (KR) 10-2006-0131919

(51) Int. Cl. G01R 27/26

(52) U.S. Cl. 324/658

(57) ABSTRACT

A capacitance measurement circuit includes a capacitor circuit unit having a first capacitor block and a second capacitor block, the first capacitor block having first and second variable capacitors connected in series and dividing an input voltage so as to supply a measurement storage voltage, and the second capacitor block having third and fourth variable capacitors connected in series and dividing the input voltage so as to supply a reference storage voltage. A voltage sensing unit senses the measurement storage voltage so as to supply the sensed measurement storage voltage as a measurement voltage and senses the reference storage voltage so as to supply the sensed reference storage voltage as a reference voltage.

### CROSS REFERENCE TO RELATED APPLICATION

This application claims priority from Korean Patent Application No. 10-2006-0131919 filed on Dec. 21, 2006 in the Korean Intellectual Property Office, the disclosure of which is incorporated herein by reference in its entirety.

### BACKGROUND OF THE INVENTION

1. Field of the Invention

Embodiments of the present invention relate to a capacitance measurement circuit and a capacitance measurement method thereof, and in particular, to a capacitance measurement circuit that can accurately measure capacitance misalignment, and a capacitance measurement method thereof.

2. Description of the Related Art

A SOC (System On Chip) configuration is often times also referred to as an LSI (Large Scale Integrated Circuit) or a system IC (Integrated Circuit), and is implemented as a single chip by integrating a circuit that otherwise would require a PCB (Printed Circuit Board) onto a single semiconductor. In other words, an SOC refers to a complete, drivable product that is mounted onto a single chip. Examples of SOCs for communication systems include a microprocessor, a DSP, a RAM, and a ROM. With the SOC, a system can be reduced in size and an assembling process thereof can be simplified.

In some systems, an SOC is implemented by integrating a known semiconductor element and a known RF circuit element into a single, common, chip. For example, mixed signal circuits that are used in RF band communication systems are formed on a silicon-based semiconductor substrate. Such a circuit employs basic passive elements, such as a resistor, a capacitor, and an inductor.

Among the passive elements that are used in a voltage controlled oscillator (VCO), a necessary element in an RF circuit, an inductor and a capacitor of the VCO are required to have high performance and to be formed with high precision. Recently, varactor diode-type capacitors have been used in the voltage controlled oscillator of a high-frequency circuit. The varactor diode-type capacitor is a variable capacitor that can acquire a frequency signal to be used for a specified frequency using a characteristic that capacitance changes according to a change in voltage. That is, in order to acquire a specified frequency signal of the voltage controlled oscillator circuit, capacitance performance of the capacitor is important. Further, in order to stabilize the frequency characteristics of the voltage controlled oscillator and a band-pass filter and to reduce the loss, stable capacitors are required. As described above, in a highly precise voltage controlled oscillator, a circuit that measures capacitance misalignment between the capacitors is needed.

However, measurement of capacitance using known capacitance measurement equipment has a measurement limit. For example, it is difficult to measure capacitance values under 100 fF. In addition, as a pseudo floating gate technique, there is known a method that calculates capacitance by varying a voltage application condition. While this method can be applied to an MIM capacitor that does not depend on an application voltage, it can not be applied to a varactor type variable capacitor, the performance of which depends on the application voltage. Therefore, it can be difficult to measure capacitance misalignment characteristics of the variable capacitor in an apparatus, to which the varactor-type variable capacitor of the high-frequency circuit is applied.

### SUMMARY OF THE INVENTION

An object of the embodiments of the invention is to provide a capacitance measurement circuit that can accurately measure capacitance to ensure stable operation of a capacitor.

Another object of the embodiment of the invention is to provide a capacitance measurement method that can accurately measure capacitance to ensure stable operation of a capacitor.

Objects of the embodiments of the present invention are not limited to those mentioned above, and other objects of the present invention will be readily understood by those skilled in the art through the following description.

In one aspect, a capacitance measurement circuit comprises: a capacitor circuit unit comprising a first capacitor block and a second capacitor block, the first capacitor block comprising first and second variable capacitors connected in series and dividing an input voltage so as to supply a measurement storage voltage, and the second capacitor block comprising third and fourth variable capacitors connected in series and dividing the input voltage so as to supply a reference storage voltage; and a voltage sensing unit sensing the measurement storage voltage so as to supply the sensed measurement storage voltage as a measurement voltage and sensing the reference storage voltage so as to supply the sensed reference storage voltage as a reference voltage.

In one embodiment, the input voltage is in a voltage range that causes the capacitors to operate in a saturation state.

In another embodiment, in the capacitor circuit unit, the first capacitor block and the second capacitor block are connected in a mirror-type configuration.

In another embodiment, the capacitance measurement circuit further comprises: an input voltage unit, wherein anodes of the first and third variable capacitors are connected to the input voltage unit.

In another embodiment, anodes of the second and fourth variable capacitors are connected to cathodes of the first and third variable capacitors, respectively.

In another embodiment, the voltage sensing unit comprises a measurement voltage sensing unit and a reference voltage sensing unit that operate exclusively.

In another embodiment, the measurement voltage sensing unit senses the measurement storage voltage of the first capacitor block so as to supply the measurement voltage.

In another embodiment, the reference voltage sensing unit senses the reference storage voltage of the second capacitor block so as to supply the reference voltage.

In another embodiment, the voltage sensing unit is connected to a first switching unit and a second switching unit that operate exclusively.

In another embodiment, the first switching unit operates the first capacitor block, and the second switching unit operates the second capacitor block.

In another embodiment, a current is applied to the voltage sensing unit to bias a sensing transistor of the voltage sensing unit.

In another aspect, a capacitance measurement method comprises: preparing a capacitance measurement circuit, the capacitance measurement circuit comprising a capacitor circuit unit comprising a first capacitor block and a second capacitor block, the first capacitor block comprising first and second variable capacitors connected in series and dividing an input voltage so as to supply a measurement storage voltage, and the second capacitor block comprising third and fourth variable capacitors connected in series and dividing the input voltage so as to supply a reference storage voltage, and a voltage sensing unit sensing the measurement storage voltage so as to supply the sensed measurement storage voltage as a measurement voltage and sensing the reference storage voltage so as to supply the sensed reference storage voltage as a reference voltage; supplying a first input voltage to the capacitor circuit unit and sensing a first measurement storage voltage from the first capacitor block so as to detect a first measurement voltage; supplying a second input voltage having a different voltage level from the first input voltage to the capacitor circuit unit and sensing a second measurement storage voltage from the first capacitor block so as to detect a second measurement storage voltage; supplying the first input voltage to the capacitor circuit unit and sensing a first reference storage voltage from the second capacitor block so as to detect a first reference voltage; supplying a second input voltage having a different voltage level from the first input voltage to the capacitor circuit unit and sensing a second reference storage voltage from the second capacitor block so as to detect a second reference voltage; and measuring capacitance misalignment between the first and third variable capacitors using the first and second measurement voltages and the first and second reference voltages.

In one embodiment, the measuring of the capacitance misalignment evaluates capacitance response of the first variable capacitor by calculating a variation between the first and second measurement voltages with respect to a variation between the first and second input voltages.

In another embodiment, the measuring of the capacitance misalignment evaluates capacitance response of the third variable capacitor by calculating a variation between the first and second reference voltages with respect to a variation between the first and second input voltages.

In another embodiment, the measuring of the capacitance misalignment measures the capacitance misalignment by calculating an increase or a decrease of a capacitance response of the first and third variable capacitors.

In another embodiment, the capacitance response of the first variable capacitor is evaluated by calculating the variation between the first and second measurement voltages with respect to the variation between the first and second input voltages, and the capacitance response of the third variable capacitor is evaluated by calculating the variation between the first and the second reference voltages with respect to the variation between the first and second input voltages.

In another embodiment, the levels of the first and second input voltages are in a voltage range that causes the variable capacitors to operate in a saturation state.

In another embodiment, the second capacitor block does not operate when the first and second measurement storage voltages are sensed from the first capacitor block.

In another embodiment, the second capacitor block does not operate when the first and second measurement storage voltages are detected.

In another embodiment, the first capacitor block does not operate when the first and second reference storage voltages are sensed from the second capacitor block.

In another embodiment, the first capacitor block does not operate when the first and second reference voltages are detected.

In another embodiment, a current is applied to the voltage sensing unit to bias a sensing transistor of the voltage sensing unit.

### BRIEF DESCRIPTION OF THE DRAWINGS

The above and other features and advantages of the embodiments of the present invention will become more apparent by describing in detail preferred embodiments thereof with reference to the attached drawings in which:

FIG. 1 is a schematic block diagram showing a capacitance measurement circuit according to an embodiment of the invention;

FIGS. 2A and 2B are graphs showing voltage dependency of an MIM capacitor and a variable capacitor;

FIG. 3 is a circuit diagram of the capacitance measurement circuit shown in FIG. 1, according to an embodiment of the present invention;

FIG. 4 is a flowchart illustrating a capacitance measurement method according to an embodiment of the invention;

FIG. 5 is a schematic block diagram showing a capacitance measurement circuit according to another embodiment of the invention; and

FIG. 6 is a circuit diagram of the capacitance measurement circuit shown in FIG. 5.

### DETAILED DESCRIPTION OF EMBODIMENTS OF THE INVENTION

Advantages and features of the embodiments of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Rather, these embodiments are provided so that this disclosure will be thorough and complete. Like reference numerals refer to like elements throughout the specification.

Hereinafter, an embodiment of the invention will be described in detail with reference to the accompanying drawings.

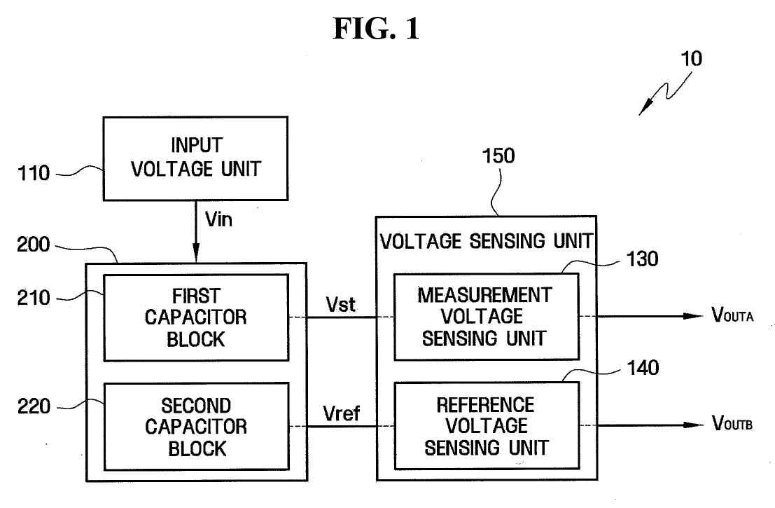

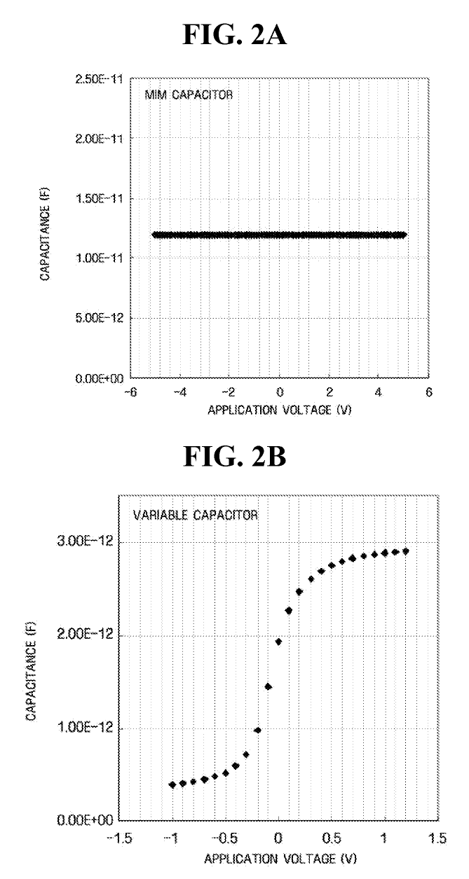

A capacitance measurement circuit according to an embodiment of the invention will now be described with reference to FIGS. 1, 2A and 2B.

FIG. 1 is a schematic block diagram of a capacitance measurement circuit according to an embodiment of the invention. FIG. 2A is a graph showing voltage dependency of an MIM capacitor. FIG. 2B is a graph showing voltage dependency of a variable capacitor.

First, referring to FIG. 1, a capacitance measurement circuit 10 includes an input voltage unit 110, a voltage sensing unit 150, and a capacitor circuit unit 200.

The input voltage unit 110 supplies an input voltage Vin to the capacitor circuit unit 200.

The capacitor circuit unit 200 receives the input voltage Vin and supplies a measurement storage voltage Vst or a reference storage voltage Vref to the voltage sensing unit 150.

The capacitor circuit unit 200 according to an embodiment of the invention includes a first capacitor block 210 and a second capacitor block 220. The first capacitor block 210 and the second capacitor block 220 receive and divide the input voltage Vin so as to supply the measurement storage voltage Vst and the reference storage voltage Vref, respectively.

The voltage sensing unit 150 senses the measurement storage voltage Vst and the reference storage voltage Vref supplied from the capacitor circuit unit 200 so as to supply a measurement voltage V_{OUTA} and a reference voltage V_{OUTB}. Further, the voltage sensing unit 150 includes a measurement voltage sensing unit 130 and a reference voltage sensing unit 140.

In particular, in the capacitance measurement circuit 10 according to an embodiment of the invention, the voltage sensing unit 150 exclusively operates in order to supply the measurement voltage V_{OUTA} and the reference voltage V_{OUTB}. Accordingly, capacitance misalignment between the variable capacitors of the first and second capacitor blocks 210 and 220 according to the input voltage Vin can be measured.

Specifically, according to an embodiment of the invention, the measurement voltage sensing unit 130 senses the measurement storage voltage Vst from the first capacitor block 210 so as to supply the sensed measurement storage voltage Vst as the measurement voltage V_{OUTA}. At this time, the reference voltage sensing unit 140 does not operate.

Meanwhile, the reference voltage sensing unit 140 senses the reference storage voltage Vref from the second capacitor block 220 so as to supply the sensed reference storage voltage Vref as the reference voltage V_{OUTB}. At this time, the measurement voltage sensing unit 130 does not operate. Accordingly, when the input voltage Vin is applied, the measurement voltage sensing unit 130 can exclude the effects from the capacitors of the second capacitor block 220 and measure the capacitance characteristics that have an effect on the first capacitor block 210. Further, the reference voltage sensing unit 140 can exclude the effects from the capacitors of the first capacitor block 210 and measure the capacitance characteristics that have an effect on the second capacitor block 220.

Referring to FIG. 2A, it can be seen that capacitance is constant regardless of the input voltage that is applied to an MIM-type capacitor. However, referring to FIG. 2B, it can be seen that capacitance of the variable capacitor changes according to the input voltage to be applied. Specifically, it can be seen that capacitance significantly varies when the input voltage to be applied has a voltage level ΔV that is near the ground voltage 0 volts. As described above, a variable capacitor, such as that used in the voltage-controlled oscillator of an RF device, uses the feature that capacitance varies according to the voltage to be applied.

The known pseudo floating gate measurement method can calculate and measure even small capacitance. However, the pseudo floating gate measurement method has a measurement condition requiring that a ground voltage level in a range of a voltage to be applied to a cathode and an anode of the MIM capacitor is to be applied. Meanwhile, as shown in FIG. 2B, in the case of the variable capacitor, the capacitance of the variable capacitor significantly varies if a predetermined voltage changes in a voltage level range near the ground voltage. Therefore, it may be difficult to measure the capacitance of a variable capacitor using the known pseudo floating gate measurement method.

In contrast, the capacitance measurement circuit 10 according to an embodiment of the present invention selects a voltage, which is used to measure capacitance both in a linear region as well as in a saturation state shown in FIG. 2B, as the input voltage Vin and applies the selected voltage to the first and second capacitor blocks 210 and 220. Here, a positive application voltage region is exemplified but the embodiments of the invention are not limited thereto. A voltage level other than a capacitance characteristic voltage level in the saturation state, that is, a voltage level other than the voltage range having a linear characteristic, may also be applied. Then, a capacitance misalignment characteristic can be measured by respectively measuring capacitances of the variable capacitors (not shown) having an application voltage dependency included in the first and second capacitor blocks 210 and 220. In particular, it is not appropriate to measure capacitance misalignment by applying a voltage having the ground voltage level to the variable capacitors to be compared. Accordingly, the capacitor blocks, are respectively provided in the variable capacitors. Then, the capacitors to be compared are selected and a voltage, which shows a stable capacitance characteristic, other than the voltage having the ground voltage level, is applied to the capacitor blocks. Therefore, a stable capacitance misalignment measurement condition can be provided for the variable capacitor having the application voltage dependency and the capacitance of the variable capacitor can be measured. This will be described below in detail with reference to a circuit diagram.

The capacitance measurement circuit according to an embodiment of the invention applies the input voltage Vin so as to measure the measurement voltage and the reference voltage, that is, the voltages divided by the individual variable capacitors. The capacitance misalignment characteristic between the variable capacitors can be recognized by calculating capacitance of the variable capacitors using the measured voltage values.

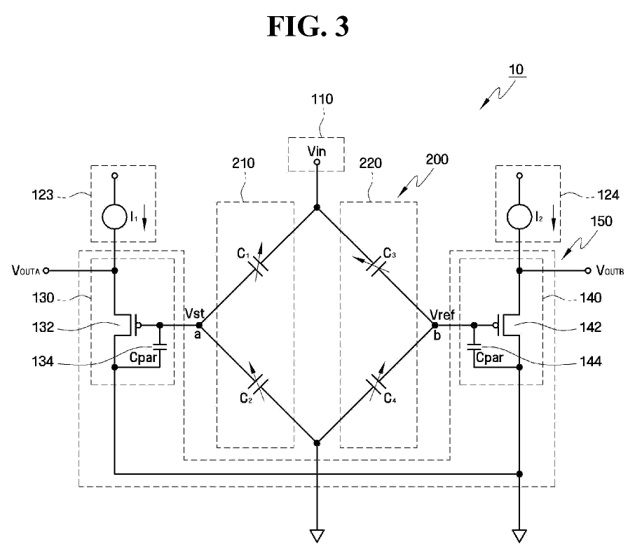

The capacitance measurement circuit according to an embodiment of the invention will be described with reference to a detailed circuit diagram of FIG. 3. FIG. 3 is a detailed circuit diagram of the capacitance measurement circuit shown in FIG. 1.

First, referring to FIG. 3, the input voltage unit 110 supplies the input voltage Vin to the capacitor circuit unit 200. The input voltage Vin has a level that presents a capacitance characteristic in the saturation state.

The capacitor circuit unit 200 includes the first capacitor block 210 and the second capacitor block 220. The first and second capacitor blocks 210 and 220 are disposed in a mirror-type configuration so as to be opposite to each other. For example, the first and second capacitor blocks 210 and 220 may be disposed in a bridge-type configuration.

The first capacitor block 210 divides the input voltage Vin and supplies the measurement storage voltage Vst to a node a.

The first capacitor block 210 includes a first variable capacitor C1 and a second variable capacitor C2 that are connected in series. An anode of the first variable capacitor C1 is connected to the input voltage unit 110. A cathode of the first variable capacitor C1 is connected to the node a and an anode of the second variable capacitor C2. A cathode of the second variable capacitor C2 is connected to ground.

When the input voltage Vin is applied to the first variable capacitor C1, the first variable capacitor C1 stores electrical charge and supplies the charged measurement storage voltage Vst to the node a. When the input voltage is applied to the first capacitor block 210, the capacitance value of the first variable capacitor C1 becomes greater than that of the second variable capacitor C2. Therefore, in the first capacitor block 210, the characteristic of the first variable capacitor C1 can be recognized by applying the input voltage Vin.

The second capacitor block 220 divides the input voltage Vin and supplies the reference storage voltage Vref to a node b.

The second capacitor block 220 includes third and fourth variable capacitors C3 and C4 that are connected in series. An anode of the third variable capacitor C3 is connected to the input voltage unit 110. A cathode of the third variable capacitor C3 is connected to the node b and an anode of the fourth variable capacitor C4. A cathode of the fourth variable capacitor C4 is connected to ground.

When the input voltage Vin is applied to the third variable capacitor C3, the third variable capacitor C3 stores electrical charge and supplies the charged reference storage voltage Vref to the node b. When the input voltage Vin is applied to the second capacitor block 220, the capacitance value of the third variable capacitor C3 becomes greater than that of the fourth variable capacitor C4. Therefore, in the second capacitor block 220, the characteristic of the third variable capacitor C3 can be recognized by applying the input voltage Vin.

The voltage sensing unit 150 senses the measurement storage voltage Vst and the reference storage voltage Vref supplied from the capacitor circuit unit 200, and, in response, supplies the measurement voltage V_{OUTA} and the reference voltage V_{OUTB}. The voltage sensing unit 150 includes the measurement voltage sensing unit 130 and the reference voltage sensing unit 140 that operate exclusively of each other. The measurement voltage sensing unit 130 is connected to the first capacitor block 210 and the reference voltage sensing unit 140 is connected to the second capacitor block 220.

In the embodiment illustrated, the measurement voltage sensing unit 130 includes a PMOS transistor 132, and the reference voltage sensing unit 140 includes a PMOS transistor 142.

Gates of the PMOS transistors 132 and 142 are connected to the node a and the node b, respectively. Sources of the PMOS transistors 132 and 142 are connected to current supply units 123 and 124, respectively. Drains of the PMOS transistors 132 and 142 are connected to the ground level. The voltages sensed at the gates of the PMOS transistors 132 and 142 are thus supplied as the measurement voltage V_{OUTA} and the reference voltage V_{OUTB}, respectively.

Parasitic capacitors 134 and 144 may exist between the gate and drain of the PMOS transistor 132 of the measurement voltage sensing unit 130 and between the gate and drain of the PMOS transistor 142 of the reference voltage sensing unit 140, respectively. Capacitance of the parasitic capacitors 134 and 144 is negligible.

The operation of the capacitance measurement circuit 10 will now be described with reference to FIG. 3.

First, a current of approximately 1 μA is applied to a first current supply unit 123 to be then supplied to the source of the PMOS transistor 132 of the measurement voltage sensing unit 130. Then, the PMOS transistor 132 operates. However, at this time, no current is supplied from the second current supply unit 124. Accordingly, the PMOS transistor 142 of the reference voltage sensing unit 140 does not operate. That is, when the measurement voltage sensing unit 130 operates, the second current supply unit 124 does not supply a current to the reference voltage sensing unit 140. Therefore, when the measurement voltage sensing unit 130 operates, it is possible to eliminate capacitance effects from the third and fourth capacitors C3 and C4 of the second capacitor block 220 connected to the reference voltage sensing unit 140.

Next, the input voltage Vin is applied from the input voltage unit 110. In one example, the input voltage Vin is in a range about of 1 V to 3 V. When a current is supplied to the first current supply unit 123, the measurement storage voltage Vst divided by the first and second variable capacitors C1 and C2 connected in series in the first capacitor block 210 is supplied to the measurement voltage sensing unit 130.

Here, when the input voltage Vin is applied, since a positive voltage is applied to the gate of the PMOS transistor 132, the PMOS transistor has an amplifier characteristic in an accumulation region. Therefore, a voltage amplified more than the measurement storage voltage Vst sensed at the node a is supplied as the measurement voltage V_{OUTA}.

Therefore, it is possible to measure the measurement voltage V_{OUTA} to be detected by a performance characteristic of the first variable capacitor C1 included in the first capacitor block 210 relative to the input voltage Vin.

Similarly, a current of approximately 1 μA is applied to a second current supply unit 124, and then the reference voltage sensing unit 140 operates. Therefore, it is possible to detect the reference voltage on the basis of the characteristics of the third and fourth capacitors C3 and C4 that are included in the second capacitor block 220 connected to the reference voltage sensing unit 140. However, since no current is supplied to the first current supply unit 123, the measurement voltage sensing unit 130 does not operate.

Here, when the input voltage Vin is applied, since a positive voltage is applied to the gate of the PMOS transistor 142, the PMOS transistor has an amplifier characteristic in an accumulation region. Therefore, a voltage amplified more than the reference storage voltage Vref sensed at the node b is supplied as the reference voltage V_{OUTB}.

Meanwhile, since the first capacitor block 210 and the second capacitor block 220 share the input voltage unit 110, a measurement error may be reduced as compared with a case where each of the first capacitor block 210 and the second capacitor block 220 includes the input voltage unit 110. Although the circuit configurations appear to be identical, in a real, physical, implementation, the physical distance from a pad to the input voltage unit 110 may vary. For this reason, the measurement error may occur due to resistance according to the real length of a wiring line. However, according to an embodiment of the invention, the error due to the physical condition can be reduced by sharing the same input voltage unit 110.

An effective characteristic of a capacitor can be measured using the measurement voltage V_{OUTA} and the reference voltage V_{OUTB} measured in the above-described manner.

Hereinafter, a method of measuring a capacitance misalignment characteristic of a capacitor will be described using the reference voltage and the measurement voltage measured through the capacitance measurement circuit according to an embodiment of the invention with reference to FIGS. 1 to 3 and 4.

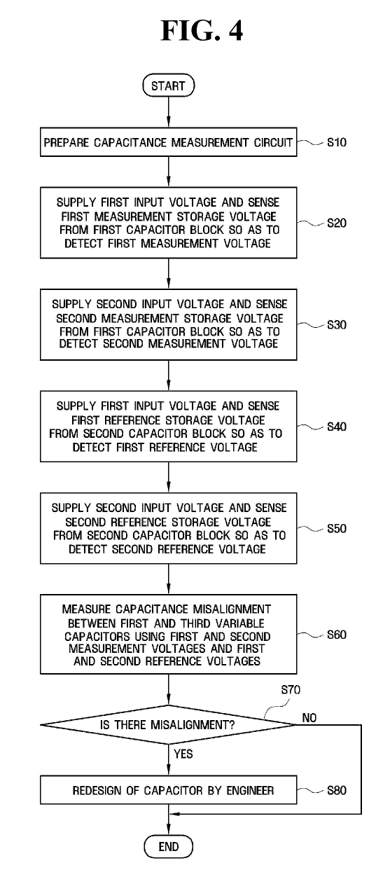

FIG. 4 is a flowchart illustrating a capacitance measurement method according to an embodiment of the invention.

First, the capacitance measurement circuit is prepared (Step S10).

In the capacitance measurement circuit 10, the capacitor circuit unit 200 that includes the first capacitor block 210 and the second capacitor block 220 is prepared. In the capacitor circuit unit 200, the first capacitor block 210 includes the first variable capacitor C1 and the second variable capacitor C2 connected in series and divides the input voltage so as to supply the measurement storage voltage Vst. The second capacitor block 220 includes the third variable capacitor C3 and the fourth variable capacitor C4 connected in series and divides the input voltage so as to supply the reference storage voltage Vref. Then, the voltage sensing unit senses the measurement storage voltage Vst so as to supply the sensed measurement storage voltage Vst as the measurement voltage V_{OUTA} and senses the reference storage voltage Vref so as to supply the sensed reference storage voltage Vref as the reference voltage V_{OUTB}.

Next, a first input voltage Vin1 is supplied, then the first measurement storage voltage Vst1 is sensed from the first capacitor block 210, and subsequently the first measurement voltage V_{OUTA1} is detected (Step S20).

First, a current, for example of approximately 1 μA, is applied to the first current supply unit 123 and then the measurement voltage sensing unit 130 operates. Further, the first input voltage Vin1 at a first level is supplied to the input voltage unit 110. At this time, the first measurement storage voltage Vst1 is sensed from the first capacitor block 210 and an operation of sensing the reference storage voltage Vref from the second capacitor block 220 is blocked.

Next, a second input voltage Vin2 at a different level from the first input voltage is supplied, then the second measurement storage voltage Vst2 is sensed from the first capacitor block 210, and subsequently a second measurement voltage V_{OUTA2} is detected (Step S30).

Here, the voltage level of each of the first and second input voltages Vin1 and Vin2 may be a voltage level that provides a capacitance characteristic in the saturation state.

Like the detection of the first measurement voltage V_{OUTA1}, an operation of sensing the reference storage voltage Vref from the second capacitor block 220 is blocked. Meanwhile, the second input voltage Vin2 is supplied, and then the second measurement voltage V_{OUTA2} is detected from the first capacitor block 210.

Next, the first input voltage Vin1 is supplied to the capacitor circuit unit 200, then the first reference storage voltage Vref1 is sensed from the second capacitor block 220, and subsequently detect the first reference voltage V_{OUTB1} is detected (Step S40).

The first input voltage Vin1 at the first level is supplied from the input voltage unit 110, and the first reference storage voltage Vref1 is sensed from the second capacitor block 220. However, an operation of sensing the measurement storage voltage Vst from the first capacitor block 210 is blocked.

The second input voltage Vin2 having a different voltage level from the first input voltage is supplied, then the second reference storage voltage Vref2 is sensed from the second capacitor block 220, and subsequently the second reference voltage V_{OUTB2} is detected (Step S50).

The second input voltage Vin2 is supplied to the capacitor circuit unit 200, and then the second reference storage voltage Vref2 divided through the third and fourth variable capacitors C3 and C4 of the second capacitor block 220 is supplied. The reference voltage sensing unit 140 senses the second reference storage voltage Vref2 so as to detect the second reference voltage V_{OUTB2}.

Next, the capacitance misalignment between the first and third variable capacitors C1 and C3 is measured using the first and second measurement voltages V_{OUTA1} and V_{OUTA2} and the first and second reference voltages V_{OUTB1} and V_{OUTB2} (Step S60).

More specifically, capacitance of the first variable capacitor C1 is acquired by calculating a variation between the first and second measurement voltages V_{OUTA1} and V_{OUTA2} with respect to a variation between the first and second input voltages Vin1 and Vin2.

Meanwhile, capacitance of the third variable capacitor C3 is acquired by calculating a variation between the first and second reference voltages V_{OUTB1} and V_{OUTB2} with respect to a variation between the first and second input voltages Vin1 and Vin2.

A description of this procedure will now be given with reference to the following equations.

$$S 1 = \frac{{V}_{OUTA 2} - {V}_{OUTA 1}}{{V}_{in 2} - {V}_{in 1}} = \frac{C 1}{C 1 + C 2 + {C}_{par}} \\ S 2 = \frac{{V}_{OUTB 2 \_} - {V}_{OUTB 1}}{{V}_{in 2} - {V}_{in 1}} = \frac{C 3}{C 3 + C 4 + {C}_{par}} \qquad [ Equation 1 ]$$

The variation between the measurement voltages V_{OUTA1} and V_{OUTA2}, as divided by the first and second variable capacitors C1 and C2 of the first capacitor block 210, with respect to the first and second input voltages Vin1 and Vin2 is calculated. The same holds true of the measurement voltages V_{OUTB1} and V_{OUTB2}. In this manner, it is possible to indirectly measure the misalignment characteristic of the capacitors by calculating a slope of the output voltages V_{OUTA} and V_{OUTB}, as measured through the variable capacitors C1 to C4 with respect to the input voltage Vin.

At this time, as described above, since the measurement storage voltage at the node a supplied through the first capacitor block 210 is stronger at the first variable capacitor Cl than at the second variable capacitor C2, the measurement storage voltage at the node a may be represented by a function of the first variable capacitor C1. Similarly, the reference storage voltage at the node b may be represented by a function of the third variable capacitor C3.

That is, the first variable capacitor C1 may be a dominant capacitor having an effect on the measurement storage voltage to be measured from the first capacitor block 210. Further, the third variable capacitor C3 may be a dominant capacitor having an effect on the reference storage voltage to be measured from the second capacitor block 220.

With the use of the above-described characteristic slopes, it is possible to measure the capacitance misalignment between the first variable capacitor C1 and the third variable capacitor C3 by the following equation.

$$\frac{Δ C}{C} = 2 \frac{S 1 - S 2}{S 1 + S 2} = 2 \frac{C 1 - C 3}{C 1 + C 3} \qquad [ Equation 2 ]$$

That is, it is possible to indirectly measure the capacitance misalignment characteristic of the capacitors using the slope characteristic of the voltage measured under the input voltage Vin condition within a predetermined range in which capacitance of the saturation state is supplied. Here, if it is assumed that the sum of C1 and C2 is the same as the sum of C3 and C4 and capacitance Cpar of the parasitic capacitors 134 and 144 is negligible, the change in characteristic of the slopes S1 and S2 means the variation of capacitance of the first and third variable capacitors C1 and C3.

In one example, if an error is less then 1%, it can be understood that capacitance between the two capacitors is aligned. If the error is, for example, more than 1%, it can be understood that capacitance between the two capacitors is misaligned (Step S70).

If it is judged that capacitance between the two capacitors is misaligned, an engineer can perform a redesign so as to minimize the capacitance misalignment, for example, by increasing or decreasing capacitance values of the capacitors, or by connecting the same capacitors in parallel (Step S80).

However, if it is judged that capacitance between the two capacitors is suitably aligned, the capacitors are regarded as stable capacitors and then they can be applied to the corresponding circuit, for example, a semiconductor memory device.

As described above, according to the embodiment of the invention, the capacitance measurement circuit and the capacitance measurement method that can extract capacitance parameters are provided, such that stable capacitors can be applied.

Specifically, a circuit that can equalize the bias conditions of the input voltages is provided but the voltages of the capacitors can be exclusively measured. Therefore, it is possible to judge whether or not capacitance between the capacitors is misaligned.

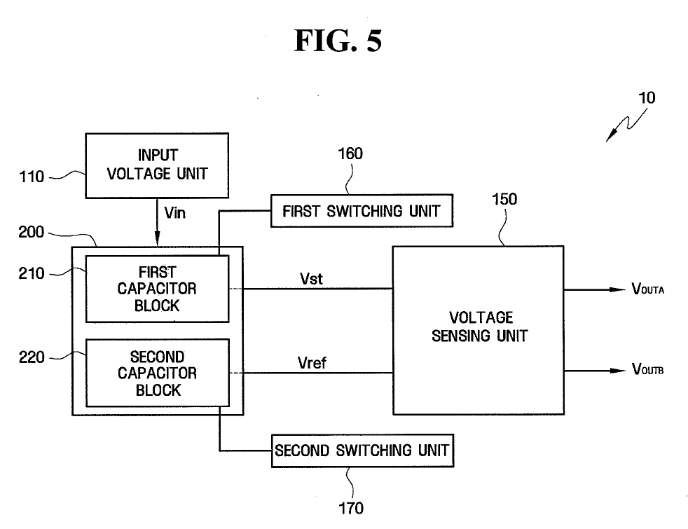

FIG. 5 is a schematic block diagram showing a capacitance measurement circuit according to another embodiment of the invention.

Referring to FIG. 5, this embodiment is different from the embodiment shown in FIG. 1 in that a first switching unit 160 controlling the first capacitor block 210 and a second switching unit 170 controlling the second capacitor block 220 are additionally provided. Further, a single voltage sensing unit 150 senses the measurement storage voltage Vst and the reference storage voltage Vref supplied from the first capacitor block 210 and the second capacitor block 220.

That is, in the above-described embodiment of the invention, the measurement voltage sensing unit 130 (see FIG. 1) is connected to the first capacitor block 210 and the reference voltage sensing unit 140 (see FIG. 1) is connected the second capacitor block 220. In contrast, according to this embodiment, a single voltage sensing unit 150 is connected to both the first capacitor block 210 and the second capacitor block 220.

According to this embodiment, in the capacitance measurement circuit 10, each of the first and second switching unit 160 and 170 connected to the first and second capacitor blocks 210 and 220, respectively, can exclusively control the first and second capacitor blocks 210 and 220. Further, the single voltage sensing unit 150 detects voltage levels supplied from the first and second capacitor blocks 210 and 220, thereby reducing a measurement error. That is, according to this embodiment, the first and second capacitor blocks 210 and 220 are separately controlled, like the above-described embodiment, but there is a single path of the voltage sensing unit 150 that detects voltages supplied from the first and second capacitor blocks 210 and 220. In this manner, it is possible to provide a capacitance measurement circuit that can further reduce the error.

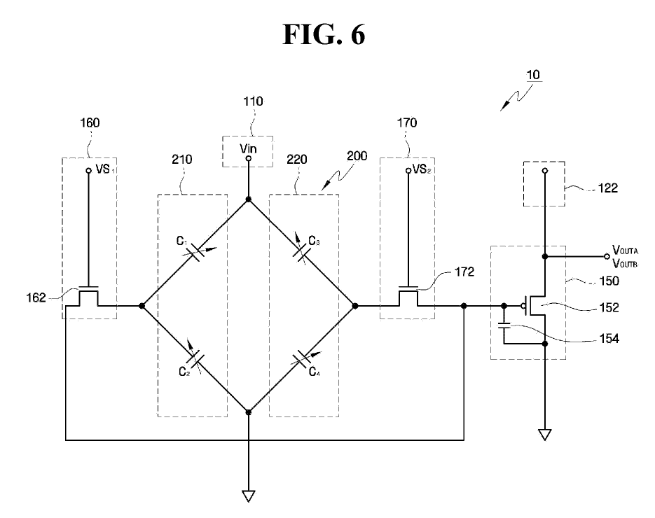

FIG. 6 is a detailed circuit diagram of the capacitance measurement circuit shown in FIG. 5.

Referring to FIG. 6, only the differences between the present embodiment and the above embodiment of FIG. 3 will be described in detail, and the descriptions of the same parts and functions as those in the FIG. 3 will be omitted.

Unlike FIG. 3, the first capacitor block 210 and the second capacitor block 220 are connected to the single voltage sensing unit 150. When a measurement storage voltage of the first capacitor block 210 is sensed, the first switching unit 160 is connected so as to turn on the voltage sensing unit 150. Further, when a reference storage voltage of the second capacitor block 220 is sensed, the second switching unit 170 is connected so as to turn on the voltage sensing unit 150..

Each of the first and second switching units 160 and 170 may be NMOS transistors 162 and 172 so as to be turned on when a positive voltage is applied and turned off when a ground voltage is applied. However, the embodiments of the invention are not limited thereto; for example each of the first and second switching units 160 and 170 may be diodes that can perform a switching function. That is, the first and second switching units 160 and 170 may be elements that satisfy the advantages of the invention and performs the switching function. Further, in order to reliably perform the switching function, a large switching element may be used. However, the switching element is used only to control the first and second capacitor blocks 210 and 220 and then may have no effect on the capacitance misalignment characteristic.

According to this embodiment, the voltage sensing-unit 150 receives a current from a current supply unit 122. Further, the voltage sensing unit 150 senses the measurement storage voltage and the reference storage voltage supplied from the first and second capacitor blocks 210 and 220 exclusively controlled by the first and second switching units 160 and 170, respectively, and supplies the sensed measurement storage voltage or the reference storage voltage as the measurement voltage V_{OUTA} or the reference voltage V_{OUTB}.

In the capacitance measurement circuit according to this embodiment, a single voltage detection path of the voltage sensing unit 150 exists, thereby reducing the measurement error, as compared with a case where the measurement voltage sensing unit and the reference voltage sensing unit are separately provided.

Since the capacitance measurement method according to this embodiment is the same as that in FIG. 4, the description thereof will be omitted.

Although the present invention has been described in connection with the exemplary embodiments of the present invention, it will be apparent to those skilled in the art that various modifications and changes may be made thereto without departing from the scope and spirit thereof. Therefore, it should be understood that the above embodiments are not limitative, but illustrative in all aspects.

As described above, the capacitance measurement circuit and the capacitance measurement method according the embodiments of the invention have at least the following advantages.

First, it is possible to accurately measure capacitance misalignment characteristics of a variable capacitor.

Second, it is possible to reduce measurement error by applying the same input voltage condition between the capacitors to be compared.

Third, it is possible to measure the capacitance misalignment of the variable capacitor, and thus it is possible to implement a capacitor that supplies stable capacitance.

Fourth, since the stable capacitor is implemented, it is possible to implement a stable circuit operation.

What is claimed is:

1. A capacitance measurement circuit comprising:
a capacitor circuit unit comprising a first capacitor block and a second capacitor block, the first capacitor block comprising first and second variable capacitors connected in series and dividing an input voltage so as to supply a measurement storage voltage, and the second capacitor block comprising third and fourth variable capacitors connected in series and dividing the input voltage so as to supply a reference storage voltage; and
a voltage sensing unit sensing the measurement storage voltage so as to supply the sensed measurement storage voltage as a measurement voltage and sensing the reference storage voltage so as to supply the sensed reference storage voltage as a reference voltage.

2. The capacitance measurement circuit of claim 1, wherein the input voltage is in a voltage range that causes the capacitors to operate in a saturation state.

3. The capacitance measurement circuit of claim 1, wherein, in the capacitor circuit unit, the first capacitor block and the second capacitor block are connected in a mirror-type configuration.

4. The capacitance measurement circuit of claim 1, further comprising:
an input voltage unit, wherein anodes of the first and third variable capacitors are connected to the input voltage unit.

5. The capacitance measurement circuit of claim 4, wherein anodes of the second and fourth variable capacitors are connected to cathodes of the first and third variable capacitors, respectively.

6. The capacitance measurement circuit of claim 1, wherein the voltage sensing unit comprises a measurement voltage sensing unit and a reference voltage sensing unit that operate exclusively.

7. The capacitance measurement circuit of claim 6, wherein the measurement voltage sensing unit senses the measurement storage voltage of the first capacitor block so as to supply the measurement voltage.

8. The capacitance measurement circuit of claim 6, wherein the reference voltage sensing unit senses the reference storage voltage of the second capacitor block so as to supply the reference voltage.

9. The capacitance measurement circuit of claim 1, wherein the voltage sensing unit is connected to a first switching unit and a second switching unit that operate exclusively.

10. The capacitance measurement circuit of claim 9, wherein the first switching unit operates the first capacitor block, and the second switching unit operates the second capacitor block.

11. The capacitance measurement circuit of claim 1, a current is applied to the voltage sensing unit to bias a sensing transistor of the voltage sensing unit.

12. A capacitance measurement method comprising:
preparing a capacitance measurement circuit, the capacitance measurement circuit comprising a capacitor circuit unit comprising a first capacitor block and a second capacitor block, the first capacitor block comprising first and second variable capacitors connected in series and dividing an input voltage so as to supply a measurement storage voltage, and the second capacitor block comprising third and fourth variable capacitors connected in series and dividing the input voltage so as to supply a reference storage voltage, and a voltage sensing unit sensing the measurement storage voltage so as to supply the sensed measurement storage voltage as a measurement voltage and sensing the reference storage voltage so as to supply the sensed reference storage voltage as a reference voltage;
supplying a first input voltage to the capacitor circuit unit and sensing a first measurement storage voltage from the first capacitor block so as to detect a first measurement voltage;
supplying a second input voltage having a different voltage level from the first input voltage to the capacitor circuit unit and sensing a second measurement storage voltage from the first capacitor block so as to detect a second measurement storage voltage;
supplying the first input voltage to the capacitor circuit unit and sensing a first reference storage voltage from the second capacitor block so as to detect a first reference voltage;
supplying a second input voltage having a different voltage level from the first input voltage to the capacitor circuit unit and sensing a second reference storage voltage from the second capacitor block so as to detect a second reference voltage; and
measuring capacitance misalignment between the first and third variable capacitors using the first and second measurement voltages and the first and second reference voltages.

13. The capacitance measurement method of claim 12, wherein the measuring of the capacitance misalignment evaluates capacitance response of the first variable capacitor by calculating a variation between the first and second measurement voltages with respect to a variation between the first and second input voltages.

14. The capacitance measurement method of claim 12, wherein the measuring of the capacitance misalignment evaluates capacitance response of the third variable capacitor by calculating a variation between the first and second reference voltages with respect to a variation between the first and second input voltages.

15. The capacitance measurement method of claim 12, wherein the measuring of the capacitance misalignment measures the capacitance misalignment by calculating an increase or a decrease of a capacitance response of the first and third variable capacitors.

16. The capacitance measurement method of claim 15, wherein the capacitance response of the first variable capacitor is evaluated by calculating the variation between the first and second measurement voltages with respect to the variation between the first and second input voltages, and the capacitance response of the third variable capacitor is evaluated by calculating the variation between the first and the second reference voltages with respect to the variation between the first and second input voltages.

17. The capacitance measurement method of claim 12, wherein the levels of the first and second input voltages are in a voltage range that causes the variable capacitors to operate in a saturation state.

18. The capacitance measurement method of claim 12, wherein the second capacitor block does not operate when the first and second measurement storage voltages are sensed from the first capacitor block.

19. The capacitance measurement method of claim 12, wherein the second capacitor block does not operate when the first and second measurement storage voltages are detected.

20. The capacitance measurement method of claim 12, wherein the first capacitor block does not operate when the first and second reference storage voltages are sensed from the second capacitor block.

21. The capacitance measurement method of claim 12, wherein the first capacitor block does not operate when the first and second reference voltages are detected.

22. The capacitance measurement method of claim 12, a current is applied to the voltage sensing unit to bias a sensing transistor of the voltage sensing unit.
